(19) United States
(12) Patent Application Publication
(10) Pub. No.: US 2012/0228443 A1
(43) Pub. Date: Sep. 13, 2012

(54) SUPPORT DEVICE AND ELECTRONIC DEVICE USING SAME

(75) Inventors: BIN DU, Shenzhen City (CN); WEN-RONG CHEN, Tu-Cheng (TW); HUI LI, Shenzhen City (CN); CONG HUANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/213,444

(22) Filed: Aug. 19, 2011

(30) Foreign Application Priority Data
Mar. 11, 2011 (CN) 201110058418.4

(51) Int. Cl. H05K 7/00; F16M 11/38; F16M 11/20

(52) U.S. Cl. 248/176.3; 248/346.01; 248/176.1

(57) ABSTRACT

A support device for supporting an electronic device, includes a pull box, two elastic threads retractably mounted in the pull box, a housing assembly comprising two first support housings, each of the first support housings is detachably mounted on the pull box by one of the elastic threads. A string retained on the pull box for hanging the pull box and the housing assembly. After the first support housings are detached from the pull box, the first support housings are mounted on the electronic device for support.

### BACKGROUND

1. Technical Field

The exemplary disclosure relates to support devices, particularly to support devices used in electronic devices.

2. Description of Related Art

Some portable electronic products will come with a bracket on the back of the casing. Thus, when the bracket is propped up, the portable electronic product can sit on the desk or other supporting planes to make it more comfortable for the users to view. Folding the bracket flush with the back of the unit makes them more convenient to carry.

However, typical brackets of the existing portable electronic products has a complicated structure as a result, it is difficult to manufacture and use them.

Therefore, there is room for improvement within the art.

### BRIEF DESCRIPTION OF THE DRAWINGS

Many aspects of the exemplary support device and electronic device using the support device can be better understood with reference to the following drawings. These drawings are not necessarily drawn to scale, the emphasis instead being placed upon clearly illustrating the principles of the present support device and electronic device. Moreover, in the drawings like reference numerals designate corresponding parts throughout the several views. Wherever possible, the same reference numbers are used throughout the drawings to refer to the same or like elements of an embodiment.

FIG. 1 is a schematic view of a support device according to an exemplary embodiment.

FIG. 2 is another view of the support device of FIG. 1 viewed from another aspect.

FIG. 3 is a partially exploded view of the support device of FIG. 1.

FIG. 4 is another partially exploded view of the support device of FIG. 1.

FIG. 5 is a schematic view of a first support housing of the support device of FIG. 1.

FIG. 6 is a schematic view of a pull box of the support device of FIG. 4.

FIG. 7 is an exploded view of the pull box of the support device of FIG. 4.

FIG. 8 is a schematic view of the support device of FIG. 2 after a string is retracted.

FIG. 9 is a schematic view of the support device supporting an electronic device.

FIG. 10 is another view of the support device supporting an electronic device of FIG. 9.

### DETAILED DESCRIPTION

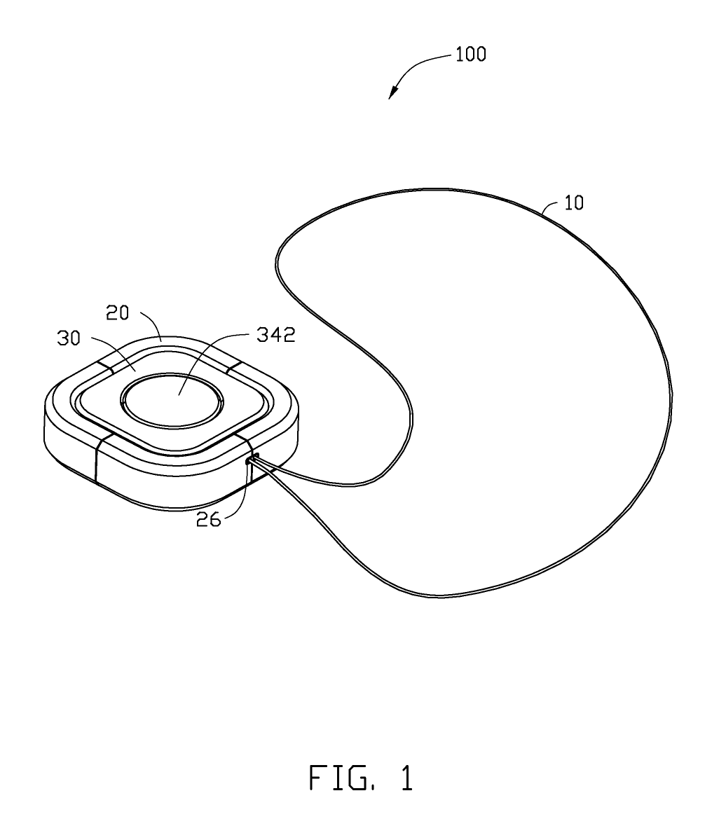

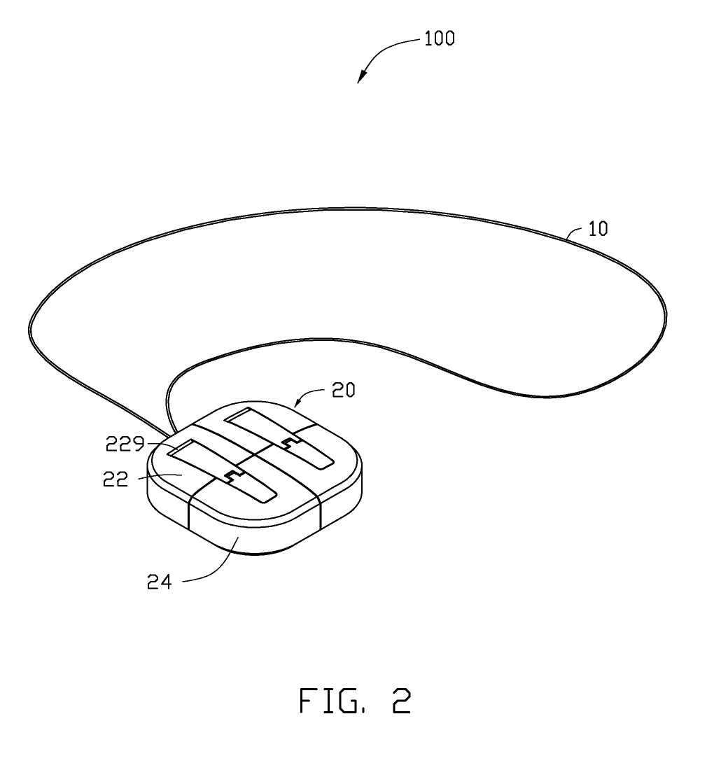

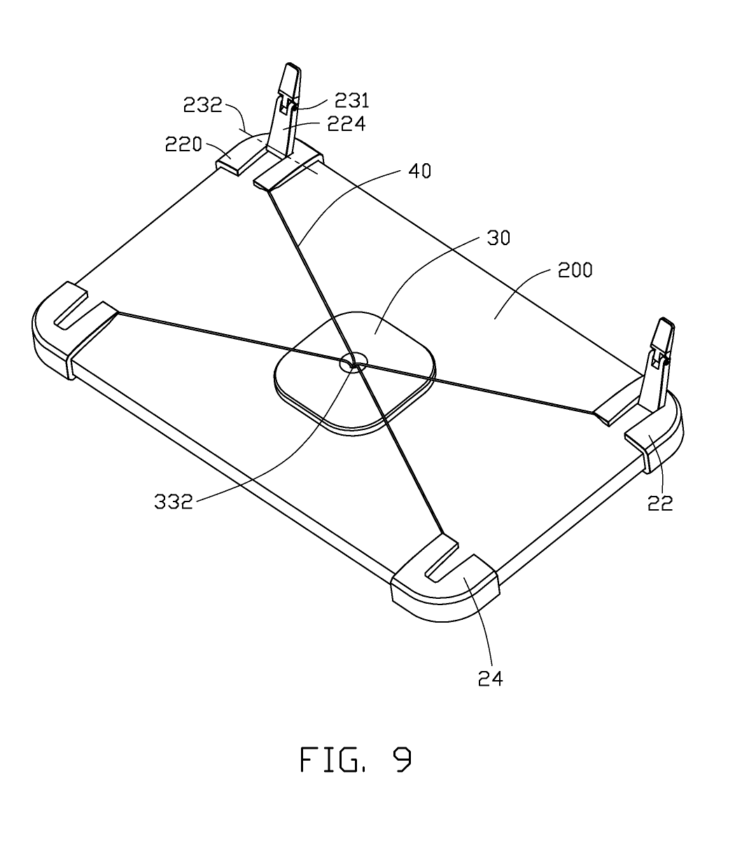

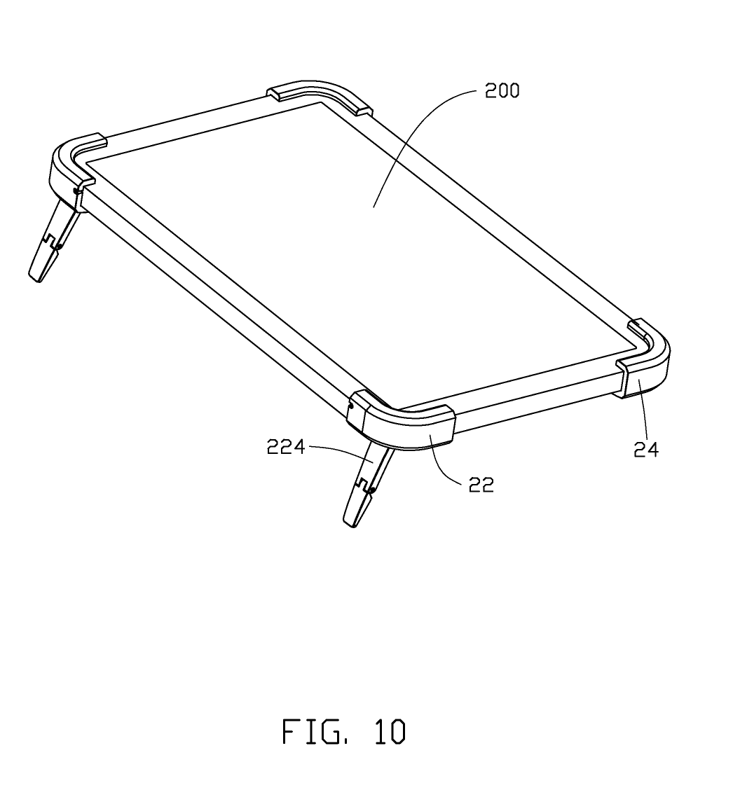

An embodiment of a support device 100 is shown in FIGS. 1 to 3. The support device 100 includes a string 10, a housing assembly 20, a pull box 30 and four elastic threads 40. In an assembled configuration shown in FIG. 1, the pull box 30 is mounted in the housing assembly 20 and the elastic threads 40 are retracted in the pull box 30 to form a pendant hung by the string 10. In a detached configuration shown in FIGS. 9 and 10, the housing assembly 20 is detached from the pull box 30 with the elastic threads 40 pulled out of the pull box 30 to support an electronic device 200.

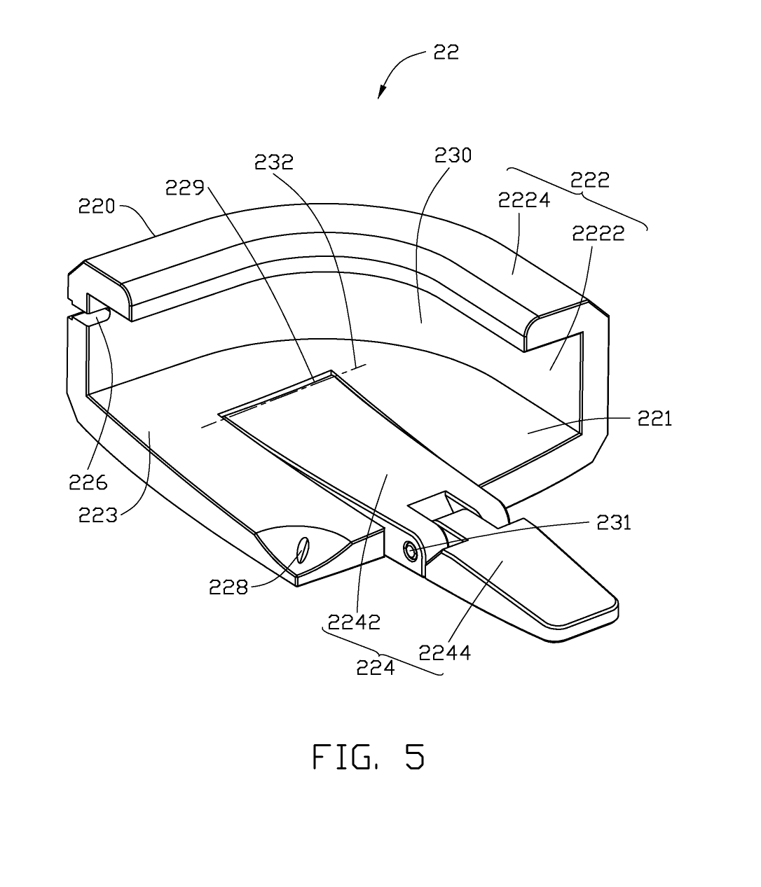

Referring to FIGS. 1, 3, and 5, the housing assembly 20 includes two first support housings 22 and two second support housings 24. Each first support housing 22 includes a first securing element 220 and a support element 224 jointed on corresponding first securing element 220. Each first securing element 220 includes a first bottom board 221 and a first flange 222 located on corresponding first bottom board 221. Each first flange 222 includes a first sidewall 2222 perpendicularly protruding from one edge of corresponding first bottom board 221, and a first extending portion 2224 protruding from a distal end of corresponding first sidewall 2222 above corresponding first bottom board 221 to form a first securing groove 230 between the first extending portion 2224, the first sidewall 2222 and the first bottom board 221. Each first sidewall 2222 may further define a notch 226 for the string 10 to pass through. Each first bottom board 221 further defines a first retaining hole 228 in another edge opposite to corresponding first sidewall 2222, in which one of the elastic threads 40 is retained. Each first bottom board 221 further defines a first receptacle 229 for accommodating a corresponding first support element 224. Each first securing element 220 has a rubber layer 223 formed in an inner surface, to prevent the electronic device 200 from being damaged when the electronic device 200 is secured in the first securing grooves 230.

Each support element 224 includes a rotation element 2242 hinged to corresponding first bottom board 221 by a shaft 232 and located in corresponding first receptacle 229, and a lengthening portion 2244 hinged to corresponding rotation element 2242 by a joint 231.

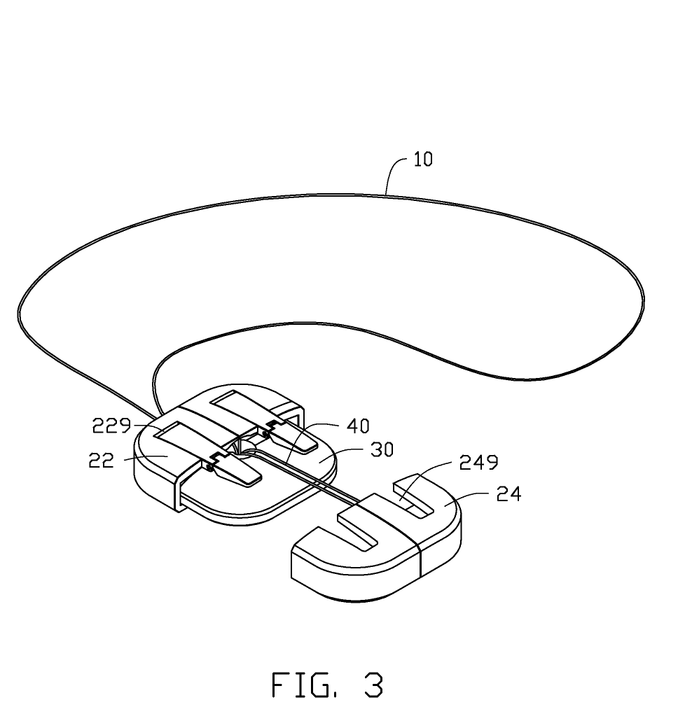

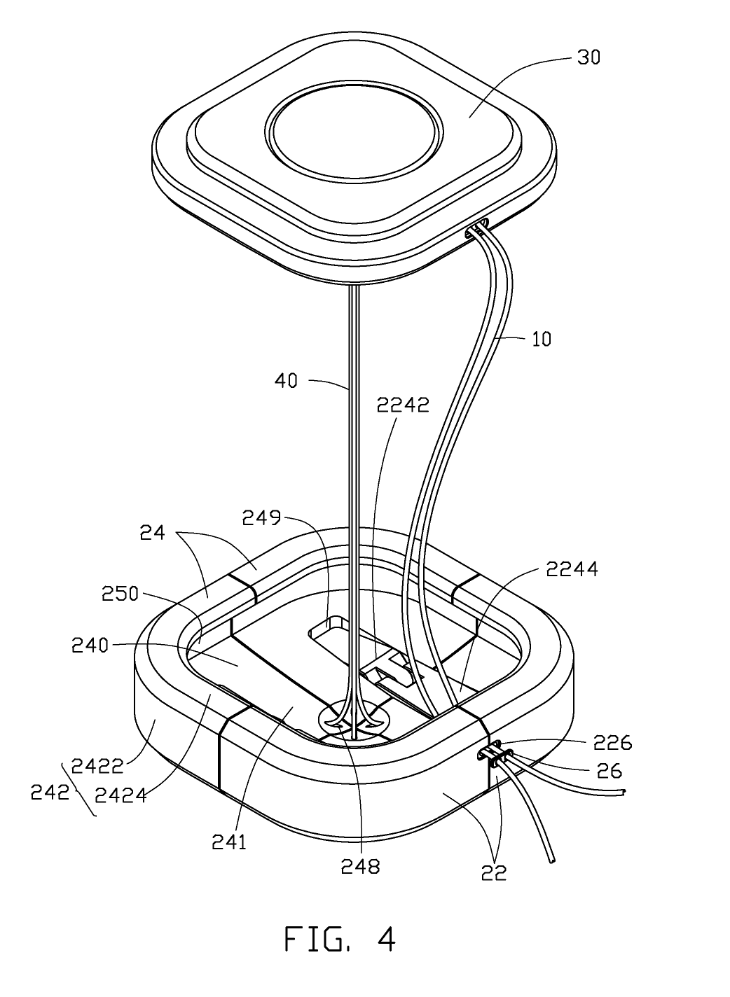

Referring to FIGS. 3 and 4, each second support housing 24 has a structure similar to one of the first support housings 22. Each second support housing 24 includes a second securing element 240, but has no support element joined on the second securing element 240. Each second securing element 240 includes a second bottom board 241 and a second flange 242 located on corresponding second bottom board 241. Each second flange 242 includes a second sidewall 2422 protruding from one edge of corresponding second bottom board 241. In addition, a second extending portion 2424 protrudes from a distal end of corresponding second sidewall 2422 above the corresponding second bottom board 241 to form a second securing groove 250 between the second extending portion 2424, the second sidewall 2422 and the second bottom board 241. Each second bottom board 241 further defines a second retaining hole 248 in another edge opposite to corresponding second sidewall 2422, in which one of the elastic threads 40 is retained. Each second bottom board 241 further defines a second receptacle 249 for accommodating corresponding lengthening portion 2244.

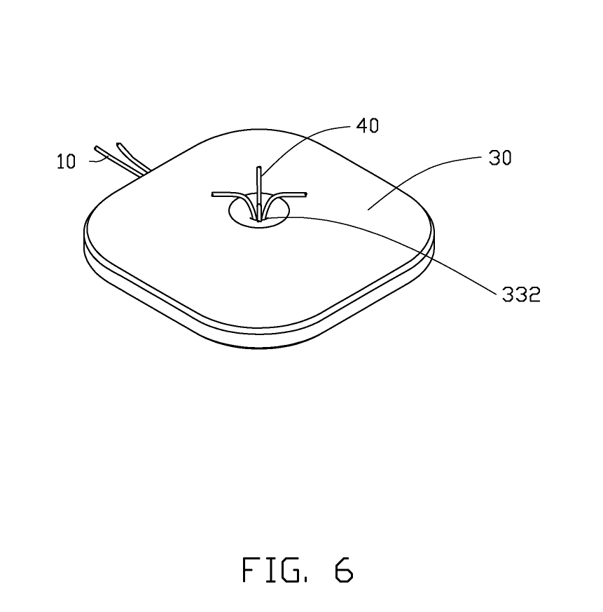

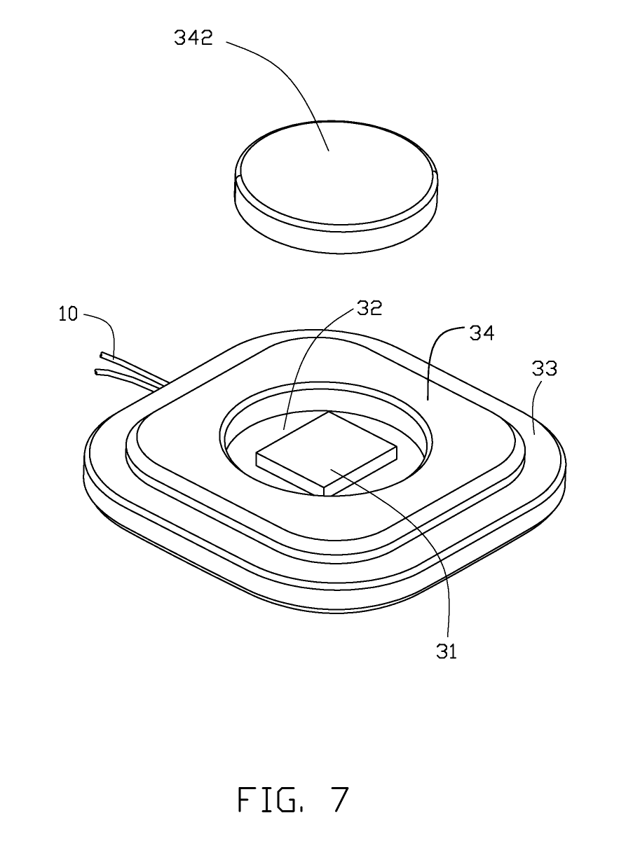

Referring to FIGS. 6 and 7, the pull box 30 includes a main body 33 and a raised portion 34 protruding one side of the main body 33. The raised portion 34 is smaller than the main body 33. The pull box 30 further defines a chamber 32 in the raised portion 34 and a pull device 31 located in the chamber 32. The main body 33 further defines an opening 332 in another side of the main body 33 opposite to the raised portion 34. One end of each elastic thread 40 passes through the opening 332 to connect with the pull device 31, and the end of each elastic thread 40 is retained in one of the first retaining holes 228 and the second retaining holes 248. The pull device 31 provides a force to pull the elastic threads 40 into the pull box 30. The pull box 30 further includes a button 342 mounted on the raised portion 34, the button 342 is used to open or close the pull box 30, for example, once the button 342 is pressed, the string 10 is retracted into the pull box 30.

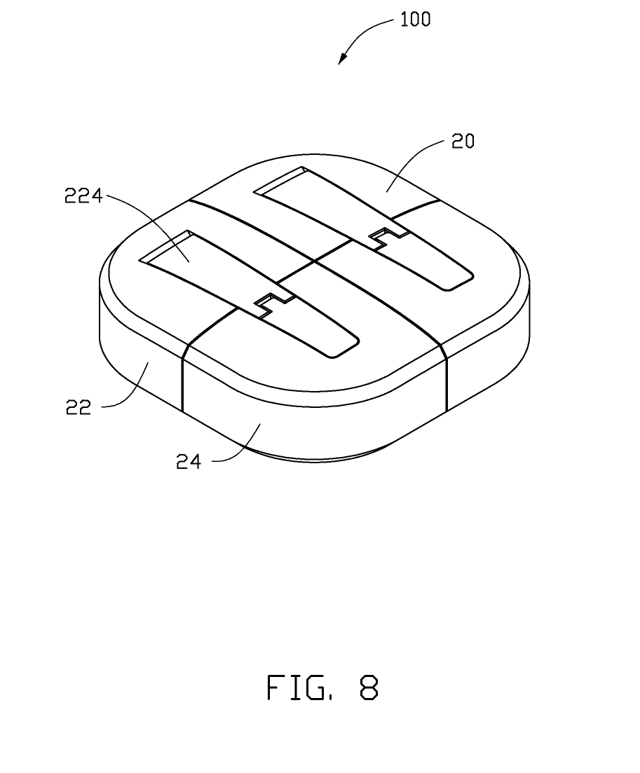

Referring to FIGS. 1 to 4 and 8, in assembly, the elastic threads 40 are pulled out of the pull box 30, and then are respectively retained in the first retaining holes 228 and the second retaining holes 248, and then the first support housings 22 and the second support housings 24 are retained on the main body 33 of the pull box 30 by the elastic force of the elastic threads 40. A center portion of the string 10 is retained on the pull box 30, two ends of the string 10 pass through the notches 226 so the string 10 is exposed from the housing assembly 20. Thus, the housing assembly 20 is mounted on the pull box 30 and the elastic threads 40 are retracted in the pull box 30 to form a pendant hung by the string 10.

In this exemplary embodiment, to prevent the string 10 being totally retracted in the pull box 30, a stopping plate 26 (FIG. 4) which is larger than the notches 226 is retained near two ends of the string 10.

In use, referring to FIGS. 9 and 10, the first support housings 22 and the second support housings 24 are respectively mounted on four corners of the electronic device 200, i.e., each corner of the electronic device 200 is secured in one of the first securing grooves 230 and the second securing grooves 250. At this time, the pull box 30 is located at/near a center of the electronic device 200, and the first support housings 22 and the second support housing 24 are steadily mounted on four corners of the electronic device 200 by the elastic force of the elastic threads 40. Then, a user can adjust the shafts 232 and the joints 231 to adjust the angle of the support elements 224 relative to the first securing elements 221 until the electronic device 200 has a comfortable viewing angle, such as shown in FIG. 10

Even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A support device for supporting an electronic device, comprising:
a housing assembly;
a pull box;
at least one elastic thread, one end of each elastic thread retained on the housing assembly, another end of each elastic thread retained on the pull box;
a string retained on the pull box;
wherein in an assembled configuration, the housing assembly is mounted on the pull box and the elastic threads are retracted in the pull box to form a pendant hung by the string; in a detached configuration, the housing assembly is detached from the pull box with each elastic thread is pulled out of the pull box to support the electronic device.

2. The support device of claim 1, wherein the housing assembly comprises two first support housings and two second support housings; the at least one elastic thread comprises four elastic threads, each of which is retained between the pull box and one of the first support housings and the second support housings.

3. The support device of claim 2, wherein each first support housing includes a first securing element securing the electronic device, and a support element jointed on corresponding first securing element to support the electronic device.

4. The support device of claim 3, wherein each first securing element comprises a first bottom board and a first flange located on corresponding first bottom board; each first flange comprises a first sidewall protruding from one edge of corresponding first bottom board, and a first extending portion protruding from a distal end of corresponding first sidewall above corresponding first bottom board to form a first securing groove between the first extending portion, the first sidewall and the first bottom board; the first securing grooves secure the electronic device therein.

5. The support device of claim 4, wherein each first sidewall further define a notch for the string to pass through.

6. The support device of claim 4, wherein each first bottom board further defines a first retaining hole in another edge opposite to corresponding first sidewall, in which said one end of one of the elastic threads is retained.

7. The support device of claim 4, wherein each first bottom board further defines a first receptacle for accommodating corresponding first support element.

8. The support device of claim 4, wherein each first securing element further has a rubber layer formed in an inner surface thereof, to prevent the electronic device from damaging when the electronic device is secured in the first securing grooves.

9. The support device of claim 4, wherein each support element comprises a rotation element hinged to corresponding first bottom board, and a lengthening portion hinged to corresponding rotation element.

10. The support device of claim 9, wherein each second support housing includes a second securing element securing the electronic device.

11. The support device of claim 10, wherein each second securing element comprises a second bottom board and a second flange located on corresponding second bottom board; each second flange comprises a second sidewall protruding from one edge of corresponding second bottom board, and a second extending portion protruding from a distal end of corresponding second sidewall above corresponding second bottom board to form a second securing groove between the second extending portion, the second sidewall and the second bottom board; the second securing grooves secure the electronic device therein.

12. The support device of claim 11, wherein each second bottom board further defines a second retaining hole in another edge opposite to corresponding second sidewall, in which said one end of one of the elastic threads is retained.

13. The support device of claim 11, wherein each second bottom board further defines a second receptacle for accommodating corresponding lengthening portion.

14. The support device of claim 11, wherein the pull box includes a main body and a raised portion protruding one side of the main body, and the raised portion is smaller than the main body; the main body secured in the first securing grooves and the second securing grooves, the raised portion resists the first flanges and the second flanges.

15. The support device of claim 14, wherein the pull box further defines a chamber in the raised portion and a pull device located in the chamber; the main body further defines an opening in another side of the main body opposite to the raised portion; each elastic thread passes through the opening to connect with the pull device; the pull device provides a force to pull the elastic threads into the pull box.

16. A support device for supporting an electronic device, comprising:
a pull box;
two elastic threads retractably mounted in the pull box;
a housing assembly comprising two first support housings, each of the first support housings detachably mounted on the pull box and retained on one of the elastic threads;
wherein after the first support housings are detached from the pull box, the first support housing are mounted on and support the electronic device.

17. The support device of claim 16, wherein each first support housing includes a first securing element securing the electronic device, and a support element jointed on corresponding first securing element to support the electronic device.

18. The support device of claim 17, wherein each first securing element comprises a first bottom board and a first flange located on corresponding first bottom board; each first flange comprises a first sidewall protruding from one edge of corresponding first bottom board, and a first extending portion protruding from a distal end of corresponding first sidewall above corresponding first bottom board to form a first securing groove between the first extending portion, the first sidewall and the first bottom board; the first securing grooves secure the electronic device therein.

19. The support device of claim 18, wherein each first sidewall further define a notch for the string to pass through.

20. The support device of claim 18, wherein each support element comprises a rotation element hinged to corresponding first bottom board, and a lengthening portion hinged to corresponding rotation element.
